(19) United States
(12) Patent Application Publication
(10) Pub. No.: US 2026/0372028 A1
(43) Pub. Date: Nov. 19, 2026

(54) METHOD FOR PRODUCING A STRUCTURE COMPRISING AT LEAST TWO TILES ON A SUBSTRATE

(71) Applicant: Soitec, BERNIN (FR)

(72) Inventors: Ionut Radu, BERNIN (FR); Bruno Ghyselen, BERNIN (FR); Christophe Maleville, BERNIN (FR)

(21) Appl. No.: 19/142,422

(22) PCT Filed: Dec. 21, 2023
(86) PCT No.: PCT/FR2023/052076

§ 371 Date: Jun. 23, 2025

(30) Foreign Application Priority Data
Dec. 22, 2022 (FR) FR2214281

(51) Int. Cl. H10P 90/00

(52) U.S. Cl. CPC H10P 90/22; H10P 90/24

(57) ABSTRACT

A method for manufacturing a composite structure includes: forming a temporary substrate comprising an intermediate substrate and a plurality of tiles of a first material; assembling the temporary substrate with a receiver substrate of a second material different from the first material via the tiles; and removing the intermediate substrate to transfer at least a portion of the tiles to the receiver substrate. The receiver substrate has a main surface from which cavities extend, the receiver substrate being assembled on the temporary substrate on the side of main surface so that each tile is received in a respective cavity. After the intermediate substrate has been removed, the free surface of the tile portions is substantially aligned with the main surface of the receiver substrate.

### CROSS-REFERENCE TO RELATED APPLICATIONS

This application is a national phase entry under 35 U.S.C. § 371 of International Patent Application PCT/FR2023/052076, filed Dec. 21, 2023, designating the United States of America and published as International Patent Publication WO 2024/134102 A1 on Jun. 27, 2024, which claims the benefit under Article 8 of the Patent Cooperation Treaty of French Patent Application Serial No. FR2214281, filed Dec. 22, 2022.

### TECHNICAL FIELD

The present disclosure relates to a process for manufacturing a structure comprising at least two tiles on a carrier substrate.

### BACKGROUND

In the field of microelectronics, optics or optoelectronics, the design of multilayer structures sometimes requires tiles, in the form of portions of a layer of a donor substrate, to be transferred onto a carrier substrate or receiver substrate.

This type of process is generally referred to as a tiling process, and involves partial transfer of a layer taken from the donor substrate to form one or more tiles arranged in a pattern or at a predetermined position on the carrier substrate.

Such tiling can be made necessary by a difference in size between the donor substrate and the carrier substrate. Specifically, due to this difference in size, it is not possible to transfer an entire layer of the donor substrate to the carrier substrate.

One well-known layer transfer process is the Smart Cut™ process, in which, by implanting atomic species in the donor substrate, a weakened zone defining the layer to be transferred is formed, the donor substrate is bonded to the carrier substrate and the donor substrate is detached along the weakened zone in order to transfer the layer from the donor substrate to the carrier substrate. However, this process assumes that the donor substrate and the carrier substrate are the same size.

While silicon substrates with a relatively large size, typically a diameter of 300 mm, are available, other materials of interest currently only exist in the form of bulk substrates of smaller size, for example, with a diameter of 10 or 15 cm. Furthermore, these materials of interest are sometimes particularly expensive, and so it is desirable to minimize the potential waste formed during the transfer. Such is the case, in particular, for III-V semiconductor materials, comprising nitrides (for example, with regard to binary compounds, indium nitride (InN), gallium nitride (GaN) and aluminum nitride (AlN)), arsenides (for example, with regard to binary compounds, indium arsenide (InAs), gallium arsenide (GaAs) and aluminum arsenide (AlAs)), and phosphides (for example, with regard to binary compounds, indium phosphide (InP), gallium phosphide (GaP) and aluminum phosphide (AlP)).

Rather than transferring an entire layer of the donor substrate, a solution based on the Smart Cut™ process involves taking from at least one donor substrate one or more tiles and transferring the tiles onto a first substrate to form what is known as a pseudo-donor substrate, forming, by implanting atomic species, a weakened zone in each tile, bonding the pseudo-donor substrate to a second substrate via the tiles, and detaching each tile along the weakened zone so to as transfer a portion of each tile onto the second substrate. The first and second substrates are the same size.

FIG. 1 shows a top view and a cross-sectional view of a carrier substrate S on which a plurality of tiles P1-P9 from at least one donor substrate have been placed. In this example, there are nine tiles, which are distributed in three rows and three columns.

However, a substrate carrying such tiles is difficult to use on the conventional microelectronics manufacturing lines used to manufacture electronic components. Such manufacturing lines include, in particular, photolithography equipment, and/or metrology equipment, the operation of which is disrupted by the height differences between the main surface of the substrate and the free surface of the tiles.

### BRIEF SUMMARY

One aim of the present disclosure is to design a process for manufacturing a composite structure comprising at least two tiles on a carrier substrate, that is compatible with the conventional microelectronics manufacturing lines.

To this end, the present disclosure proposes a process for manufacturing a composite structure comprising at least two tiles on a substrate, comprising:
(a) forming a temporary substrate comprising an intermediate substrate and a plurality of tiles made from a first material placed on the intermediate substrate,
(b) assembling the temporary substrate with a receiver substrate made from a second material different from the first material via the tiles, and
(c) removing the intermediate substrate so as to transfer at least one portion of the tiles onto the receiver substrate in order to form the composite structure,
the process being characterized in that the receiver substrate comprises a main surface from which extend cavities, the receiver substrate being assembled on the temporary substrate on the side of the main surface so that each tile is received in a respective cavity, and in that, after the intermediate substrate has been removed, the free surface of the tile portions is substantially aligned with the main surface of the receiver substrate.

“Substantially aligned” means that the surface of the tiles and the main surface of the receiver substrate, which are flat surfaces, are either coplanar or parallel and separated by a distance (measured in a direction perpendicular to the surfaces) of between 1% and 10% of the thickness of the transferred portion. In the case of a non-zero distance, the surface of the tile portions can be raised relative to the main surface of the receiver substrate or, conversely, the main surface of the receiver substrate can be raised relative to the surface of the tile portions. In general, it is ensured that the distance is less than approximately 50 nm.

In some embodiments, the step (a) of forming the temporary substrate comprises forming a weakened zone of each tile defining a respective tile portion to be transferred, and the step (c) of removing the intermediate substrate comprises detaching each tile portion along the weakened zone.

The formation of the weakened zone advantageously comprises implanting atomic species in each tile.

In some embodiments, the formation of the temporary substrate comprises taking each tile from at least one donor substrate made from the first material and placing each tile on the intermediate substrate, each donor substrate having a smaller diameter than the intermediate substrate.

In some embodiments, the second material is advantageously a semiconductor material such as silicon or silicon carbide, a piezoelectric material, or glass.

In some embodiments, the receiver substrate is a semiconductor-on-insulator substrate comprising in succession a base substrate, an electrically insulating layer and a layer of the second material defining the main surface of the receiver substrate, and the cavities are formed in the layer of the second material as far as the electrically insulating layer.

Alternatively, the cavities are formed in a surface region of the receiver substrate made up of the second material.

At least part of the walls of at least one of the cavities can advantageously be covered with an electrically insulating film, so as to electrically insulate the respective tile portion from the receiver substrate.

In other embodiments, the receiver substrate comprises at least one surface layer of the second material covered with an electrically insulating layer and the cavities are formed in the electrically insulating layer.

Preferably, the temporary substrate can be assembled on the receiver substrate by molecular adhesion.

Particularly advantageously, each tile has a thickness of between 20 μm and 1,000 μm, preferably between 100 μm and 700 μm, and the transferred portion of each tile has a thickness of between 30 nm and 1.5 μm.

Each cavity can then have a depth of between 30 nm and 1.5 μm.

In some embodiments, following the step (c) of removing the intermediate substrate, the free surface of the tile portions is raised relative to the main surface of the receiver substrate, the process further comprising a step of polishing the surfaces.

According to advantageous embodiments, the first material is selected from:
a semiconductor material, such as a III-V material, in particular, indium nitride (InN), gallium nitride (GaN), aluminum nitride (AIN), indium arsenide (InAs), gallium arsenide (GaAs), aluminum arsenide (AlAs), indium phosphide (InP), gallium phosphide (GaP) or aluminum phosphide (AlP), or a IV or IV-IV material, in particular, germanium or silicon carbide (SiC),
a piezoelectric material, such as lithium tantalate (LiTaO₃), lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and lead titanate (PMN-PT), zinc oxide (ZnO), aluminum nitride (AlN) or aluminum-scandium nitride (AlScN), and/or
an electrically insulating material, such as diamond, strontium titanate, yttria-stabilized zirconia or sapphire.

In some embodiments, the process comprises, before the step (b) of assembling the temporary substrate and the receiver substrate, the formation by epitaxy of at least one additional layer of a third material on each tile.

The cavities can be formed by chemical etching through a mask having openings in the position of the cavities.

Preferably, each cavity is sized to receive a single tile, each cavity being the same shape as the tile.

Another object of the present disclosure relates to a composite structure comprising:
at least two tiles made from a first material, and
a substrate, referred to as the receiver substrate, made from a second material different from the first material, having a main surface,

the composite structure being characterized in that the tiles are arranged in respective cavities extending in the receiver substrate from the main surface, so that a free surface of the tiles is substantially aligned with the main surface of the receiver substrate.

In some embodiments, the second material is a bulk semiconductor material such as silicon or silicon carbide, a piezoelectric material or glass, or a stack of a plurality of layers of different semiconductor materials.

In other embodiments, the receiver substrate is a semiconductor-on-insulator substrate comprising in succession a base substrate, and electrically insulating layer and a layer of the second material defining the main surface of the receiver substrate, and the cavities extend in the layer of the second material as far as the electrically insulating layer.

In other embodiments, the cavities extend in a surface region of the receiver substrate made up of the second material.

In some embodiments, at least part of the walls of at least one of the cavities is covered with an electrically insulating film.

In other embodiments, the receiver substrate comprises at least one surface layer of the second material covered with an electrically insulating layer and the cavities are formed in the electrically insulating layer.

Particularly advantageously, the first material is selected from:
a semiconductor material, such as a III-V material, in particular, indium nitride (InN), gallium nitride (GaN), aluminum nitride (AlN), indium arsenide (InAs), gallium arsenide (GaAs), aluminum arsenide (AlAs), indium phosphide (InP), gallium phosphide (GaP) or aluminum phosphide (AlP), or a IV or IV-IV material, in particular, germanium or silicon carbide (SiC),
a piezoelectric material, such as lithium tantalate (LiTaO₃), lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and lead titanate (PMN-PT), zinc oxide (ZnO), aluminum nitride (AlN) or aluminum-scandium nitride (AlScN), and/or
an electrically insulating material, such as diamond, strontium titanate, yttria-stabilized zirconia or sapphire.

### BRIEF DESCRIPTION OF THE DRAWINGS

Other features and advantages will become apparent from the following detailed description, with reference to the appended drawings, in which:

FIG. 1 is a schematic cross-sectional view of a composite structure according to one embodiment;

FIGS. 2A to 2D illustrate steps of forming the temporary substrate;

FIGS. 3A to 3H illustrate different steps of preparing the receiver substrate and transferring the tiles from the temporary substrate onto the receiver substrate, according to a first embodiment;

FIGS. 4A to 4F illustrate different steps of preparing the receiver substrate and transferring the tiles from the temporary substrate onto the receiver substrate, according to a second embodiment; and

FIGS. 5A to 5F illustrate different steps of preparing the receiver substrate and transferring the tiles from the temporary substrate onto the receiver substrate, according to a third embodiment.

For the sake of legibility, the drawings have not necessarily been drawn to scale. Furthermore, the number of tiles schematically shown in the drawings is given only by way of illustration.

### DETAILED DESCRIPTION

The present disclosure proposes a process for manufacturing a composite structure comprising at least two tiles on a substrate making it possible to place the tiles in cavities of the substrate, so as to make the surface of the tiles substantially flush with the main surface of the substrate.

The tiles are formed from a first material, which is preferably selected from:
a semiconductor material, such as a III-V material, in particular, indium nitride (InN), gallium nitride (GaN), aluminum nitride (AlN), indium arsenide (InAs), gallium arsenide (GaAs), aluminum arsenide (AlAs), indium phosphide (InP), gallium phosphide (GaP) or aluminum phosphide (AlP), or a IV or IV-IV material, in particular, germanium or silicon carbide (SiC),
a piezoelectric material, such as lithium tantalate (LiTaO₃), lithium niobate (LiNbO₃), potassium-sodium niobate (KₓNa₁₋ₓNbO₃ or KNN), barium titanate (BaTiO₃), quartz, lead zirconate titanate (PZT), a compound of lead-magnesium niobate and lead titanate (PMN-PT), zinc oxide (ZnO), aluminum nitride (AIN) or aluminum-scandium nitride (AlScN), and/or
an electrically insulating material, such as diamond, strontium titanate, yttria-stabilized zirconia or sapphire.

Some of these materials are only available in the form of substrates with small dimensions, for example, having a diameter of less than 150 to 200 mm. However, a composite structure that is as large as possible is generally sought, for example, on the order of 300 mm.

This size difference between the substrate made from the first material and the composite structure is compensated for by not directly transferring a layer of the first material onto the substrate of the composite structure, but forming a temporary structure comprising an intermediate substrate and a plurality of tiles made from the first material placed on the intermediate substrate.

In order to form the temporary substrate, tiles are taken from at least one donor substrate made from the first material and each tile is placed on an intermediate substrate. Each donor substrate typically has a smaller diameter than the intermediate substrate, but the intermediate substrate has the same diameter as the composite structure. Depending on the tiling density on the surface of the substrate, it can be necessary to use a plurality of donor substrates.

Depending on the composition of the first material, each donor substrate can have a thickness of between 20 μm and 1,000 μm, preferably between 100 μm and 700 μm. In principle, particularly for the weakest materials, tiles are cut from each donor substrate that extend over the entire thickness of the donor substrate. As a result, the thickness of the tiles is generally equal to the thickness of the donor substrate(s), and is therefore typically between 20 μm and 1,000 μm, preferably between 100 μm and 700 μm.

The tiles can be placed on the intermediate substrate by a robot, in a process known as “pick and place.”

As the intermediate substrate essentially acts as a temporary mechanical carrier for the tiles before they are transferred onto another substrate to form the composite structure, the intermediate structure can be made from any material that is sufficiently stiff to withstand the steps of the process. For example, not non-limitingly, the intermediate substrate can be made from silicon.

In some embodiments, at least one additional layer can be grown on the tiles after they have been placed on the intermediate substrate. The additional layer can be formed, for example, by epitaxy of a third material on the first material. The third material can be identical to the first material, in which case the additional layer makes it possible to thicken the tiles. In other applications, the third material can be different from the first material. In order to preserve the crystalline quality of the additional layer, the third material is preferably selected so that its lattice parameter and thermal expansion coefficient are sufficiently close to those of the first material. For example, if the first material is InP, the third material can be InGaAs, InAlAs, GaAs, etc. Hereinafter, the stack made up of the tile initially placed on the intermediate substrate and the additional layer(s) subsequently formed will be referred to as a “tile.”

In some embodiments, a weakened zone is formed in each tile so as to define a respective tile portion intended to be transferred subsequently to the substrate of the composite structure. The thickness of the tile portion to be transferred is advantageously between 30 nm and 1.5 μm.

In a manner known per se, such a weakened zone can be formed by implanting atomic species in each tile. The species typically comprise hydrogen and/or helium.

The temporary substrate is then assembled with a receiver substrate via the tiles.

The receiver substrate comprises a second material different from the first material.

Particularly advantageously, the second material is selected from semiconductor materials, such as silicon or silicon carbide, piezoelectric materials, or glass. The second material can optionally comprise a stack of a plurality of different semiconductor materials, for example, Si/SiGe, Si/SiGe/Si, etc.

The receiver substrate is not necessarily made up of a single material. In some embodiments, the receiver substrate can thus be a semiconductor-on-insulator substrate. Such a substrate comprises in succession a base substrate, an electrically insulating layer and a layer of the second material. In other embodiments, the receiver substrate can comprise an electrically insulating layer, for example, a silicon oxide, covering the second material.

The receiver substrate does not have a flat main surface, but has cavities that extend in the thickness of the receiver substrate from the main surface.

The cavities are, in the plane of the main surface of the receiver substrate, slightly larger in size than the tiles (the cavities and tiles preferably being the same shape) and are distributed in a similar pattern to the tiles, each cavity being intended to receive a respective tile. Alternatively, a cavity can be intended to receive a plurality of adjacent tiles. In this case, the size of the cavity is suitable for receiving all of the respective tiles.

The cavities also have a depth that is less than the thickness of the tiles. When the temporary substrate is assembled on the receiver substrate, each tile is thus received over at least part of its thickness in a respective cavity and adheres to the bottom of the cavity.

For example, if the tiles do not comprise a weakened zone, the depth of the cavities can be between 20 μm and 1,000 μm, preferably between 100 μm and 700 μm.

If the tiles have a weakened zone, the depth of the cavities can be approximately equal to the thickness of the layer to be transferred delimited by the weakened zone. For example, the depth of the cavities can be between 30 nm and 1.5 μm.

In some embodiments, the cavities are formed by etching the second material, which is on the surface of the receiver substrate. To this end, a mask can be formed in advance on the surface of the receiver substrate so as to cover the zones to be protected. The mask can typically be made from silicon nitride or silicon oxide. The mask has openings defining the surface to be etched to form the cavities. The etching is then carried out, for example, wet etching (the etching agent can be HF, TMAH, KOH) or dry etching (for example, reactive ion etching or RIE), in order to remove the second material. The etching time is selected as a function of the desired thickness of the cavities.

If the receiver substrate is a semiconductor-on-insulator substrate, the electrically insulating layer advantageously acts as an etch-stop layer, so that the cavities extend over the entire thickness of the layer of the second material, as far as the electrically insulating layer.

In other embodiments, if the second material is covered with an electrically insulating layer, the cavities are formed by etching the material of the electrically insulating layer. In this case, the second material advantageously acts as an etch-stop layer, so that the cavities extend over the entire thickness of the electrically insulating layer, as far as the second material. The remaining zones of the electrically insulating layer make it possible to electrically insulate adjacent tiles.

In some embodiments, after the cavities have been etched, an electrically insulating layer is formed on the wall and bottom of the cavities. Such an electrically insulating layer can, for example, be formed by oxidation of the second material during annealing in an oxidizing atmosphere. Alternatively, the electrically insulating layer can be formed through a deposition process, for example, chemical vapor deposition (CVD). The layer thus formed makes it possible to electrically insulate the tiles from the receiver substrate and electrically insulate adjacent tiles. The oxide layer can optionally act as a bonding layer for the tiles.

If the cavities have been formed in an electrically insulating layer covering the second material, it is possible to deposit an additional electrically insulating layer solely on the bottom of the cavities, in order to electrically insulate the tiles from the receiver substrate.

Finally, the intermediate substrate is removed so as to transfer at least one portion of the tiles onto the receiver substrate in order to form the composite structure.

In some embodiments, the intermediate substrate can be removed by removing material, for example, by grinding the intermediate substrate from its face opposite the receiver substrate.

In other embodiments, if the tiles comprise a weakened zone, the tiles are detached along the weakened zone, which detachment can be initiated by mechanical, thermal and/or chemical stress. The intermediate substrate and the remainder of the tiles can then be detached from the receiver substrate, the portion of the tiles defining the weakened zone being transferred onto the receiver substrate.

Preferably, the free surface of the tile portions is slightly raised relative to the free surface of the receiver substrate. For example, the free surface of the tile portions protrudes by a height of between 1% and 10% of the total thickness of the transferred portion from the free surface of the receiver substrate. The surface of the tiles can then be polished, in order to remove the zone potentially damaged during implantation and to bring the tiles to a uniform thickness. The polishing can be chemical mechanical polishing (CMP). Following polishing, the free surface of the tiles is substantially aligned with the free surface of the receiver substrate.

As the tiles or tile portions are housed in the cavities, the composite structure formed by the receiver substrate and the tiles or tile portions has a flat surface. During the subsequent steps implemented on the composite structure, in particular, the photolithography or metrology steps, overlay defects or measurement errors are thus avoided.

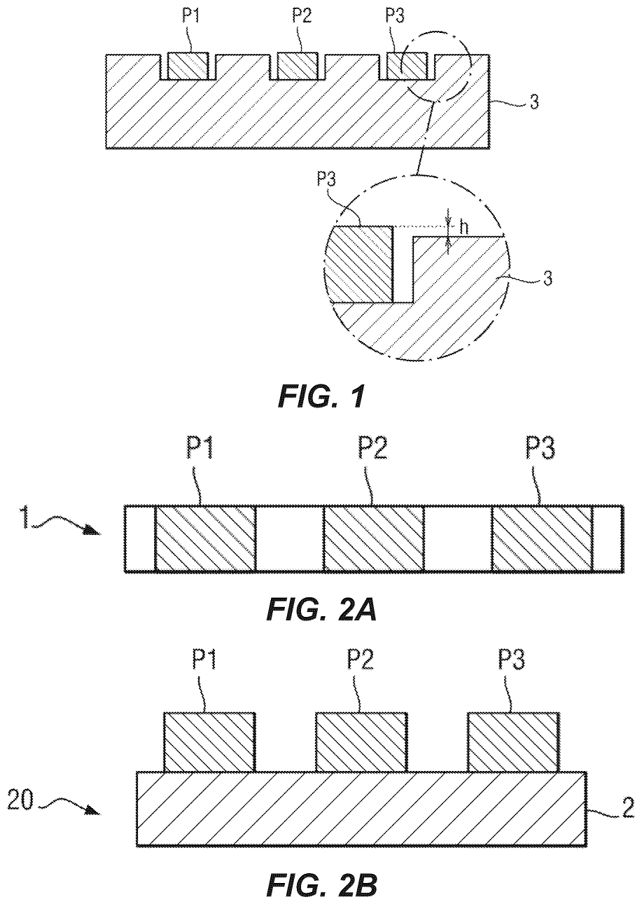

FIG. 1 is a schematic cross-sectional view of a composite structure according to one embodiment. The structure comprises tiles P1, P2, P3 made from the first material and a substrate 3 made from the second material. Each tile is arranged in a respective cavity of the substrate 3 formed in the main surface of the substrate 3, such that the free surface of the tiles is substantially aligned (coplanar) with the surface of the substrate 3.

As can be seen more clearly in the insert, which shows an enlarged view of the tile P3 in its cavity, the free surface of each tile is situated at a height h relative to the surface of the substrate 3. The height h can be zero (the free surface of the tiles and the main surface of the substrate being coplanar), positive (the tiles then being slightly raised relative to the main surface of the substrate) or negative (the tiles then being slightly recessed relative to the main surface of the substrate). As an absolute value, the height h is typically between 1 and 10% of the total thickness of the transferred portion of the tiles.

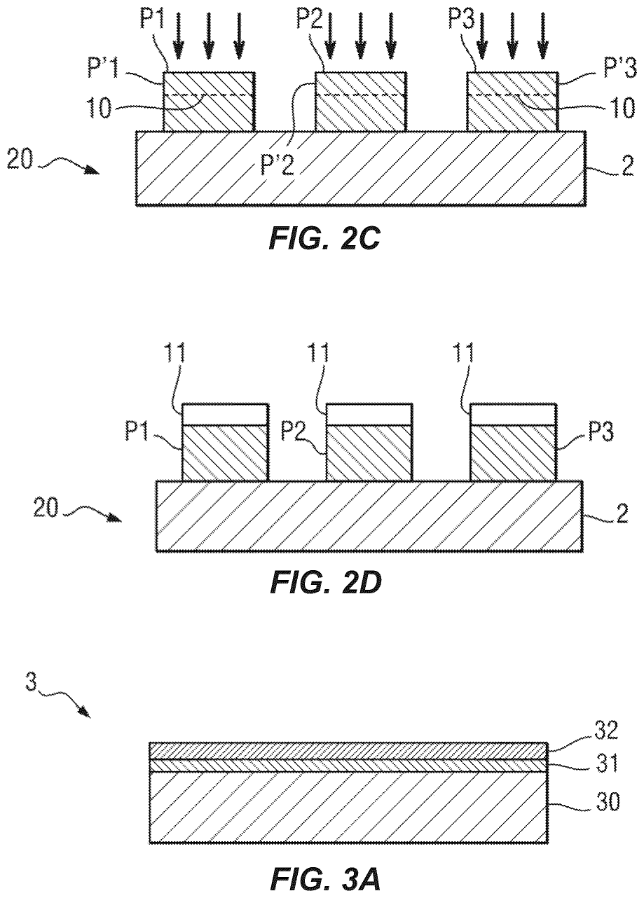

FIGS. 2A to 2D illustrate steps of forming the temporary substrate.

With reference to FIG. 2A, tiles P1, P2, P3 are cut from a donor substrate 1 made from the first material. Generally, in order not to weaken the tiles, the tiles are cut through the entire thickness of the donor substrate.

With reference to FIG. 2B, each tile P1, P2, P3 is placed on an intermediate substrate 2. As stated above, the intermediate substrate acts as a mechanical carrier for the tiles before they are transferred onto the final substrate to form the composite structure. The tiles can be placed individually (tile by tile) by way of a robot.

In some embodiments, with reference to FIG. 2C, a weakened zone 10 can be formed in each tile P1, P2, P3 placed on the intermediate substrate 2, so as to define a surface portion P′1, P′2, P′3. The weakened zone can, in particular, be formed by implanting atomic species (schematically shown with arrows) in the tiles.

In some embodiments, with reference to FIG. 2D, an additional layer 11 can be formed on the tiles P1, P2, P3 placed on the intermediate substrate 2. The additional layer can advantageously be formed by epitaxy on each tile.

Depending on the circumstances, in the rest of the process for forming the composite structure, the substrate 20 illustrated in FIGS. 2B, 2C and 2D is used as the temporary substrate. The embodiments in FIGS. 2C and 2D can optionally be combined. In this case, the additional layer is advantageously produced before implantation of the atomic species, in order to prevent the thermal budget of the growth of the additional layer from causing the premature fracturing of the tiles along the weakened zone.

The temporary substrate is intended to be assembled on a receiver substrate, in order to transfer the tiles or tile portions thereto.

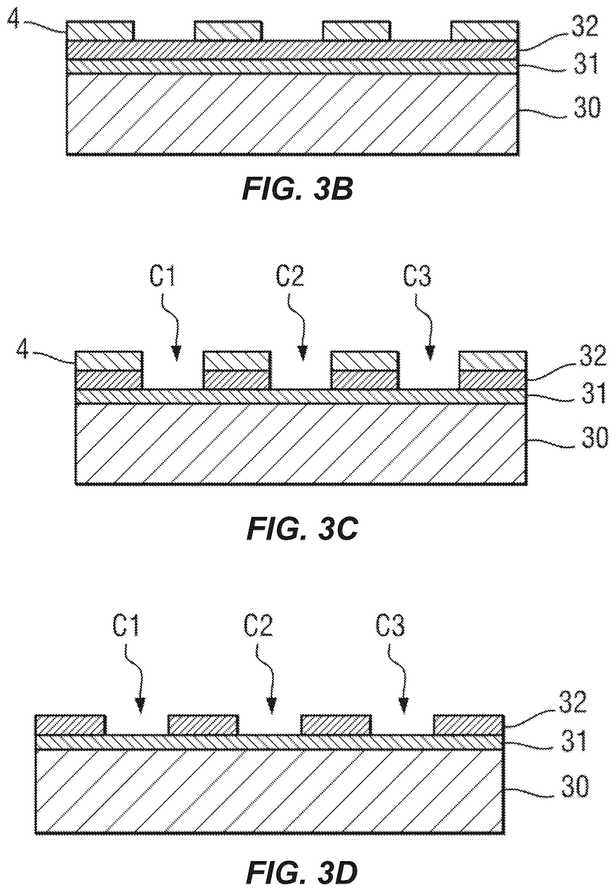

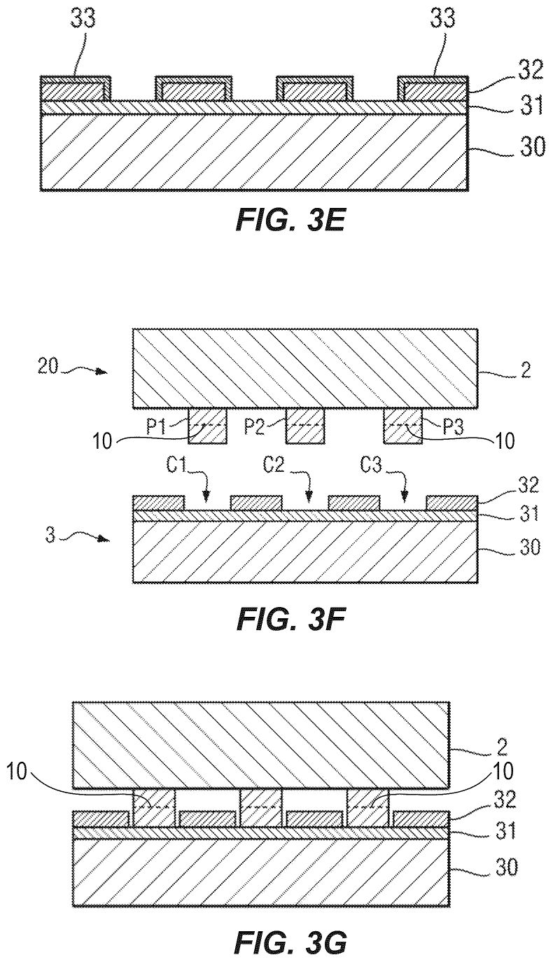

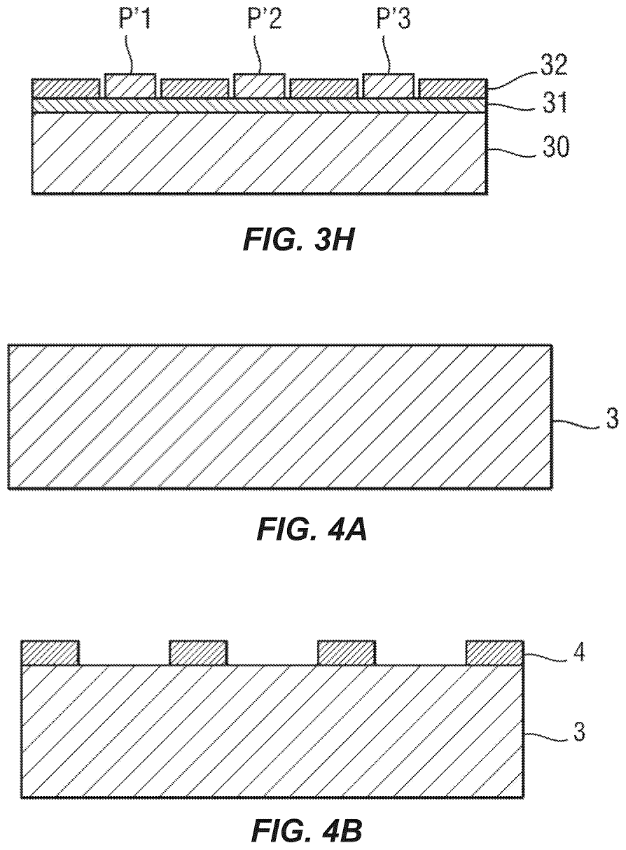

FIGS. 3A to 3H illustrate different steps of preparing the receiver substrate and transferring the tiles from the temporary substrate onto the receiver substrate, when the receiver substrate is a semiconductor-on-insulator substrate.

With reference to FIG. 3A, the receiver substrate 3 comprises in succession a base substrate 30, an electrically insulating layer 31, for example, silicon oxide (also referred to as a buried oxide layer), and a layer 32 of the second material.

With reference to FIG. 3B, a mask 4 is formed on the layer 32, the mask having openings in the position of the cavities to be formed.

With reference to FIG. 3C, the second material exposed by the openings in the mask 4 is etched, preferably over the entire thickness of the layer 32, in order to form cavities C1, C2, C3. The electrically insulating layer 31 effectively forms an etch-stop layer.

With reference to FIG. 3D, the mask 4 is removed so as to free the surface of the remaining layer 32. The substrate thus obtained can be used as a receiver substrate for receiving the tiles.

In one optional embodiment, before the receiver substrate and the temporary substrate are assembled, an electrically insulating layer 33 can be formed on the walls of the cavities. The walls and the bottom of the cavities are thus covered with the electrically insulating material, which makes it possible to electrically insulate the tiles that will be transferred into the cavities from the portions of the layer 32 that extend between the cavities and the base substrate 30.

With reference to FIG. 3F, the receiver substrate 3 and the temporary substrate 20 are assembled, placing the tiles P1, P2, P3 and the corresponding cavities C1, C2, C3 facing each other (in this figure, the substrate from FIG. 3D is shown, but the substrate from FIG. 3E could alternatively be used).

As illustrated in FIG. 3G, the adhesion of the substrates 3 and 20 takes place via the tiles and the bottom of the cavities.

With reference to FIG. 3H, the intermediate substrate is removed. In the embodiment illustrated, the tiles have a weakened zone 10. As a result, the intermediate substrate and the rest of the tiles are removed by detachment along the weakened zone 10. Only the tile portions P′1, P′2, P′3 are thus transferred onto the receiver substrate.

In other embodiments (not illustrated), the intermediate substrate can be removed by grinding the substrate from the face opposite the receiver substrate, until the main surface of the substrate 3 is reached.

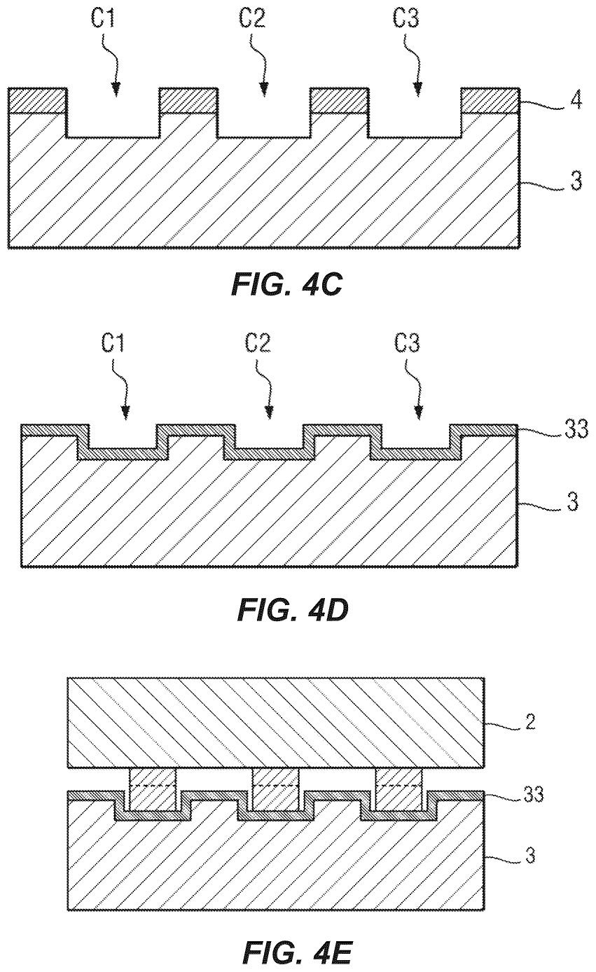

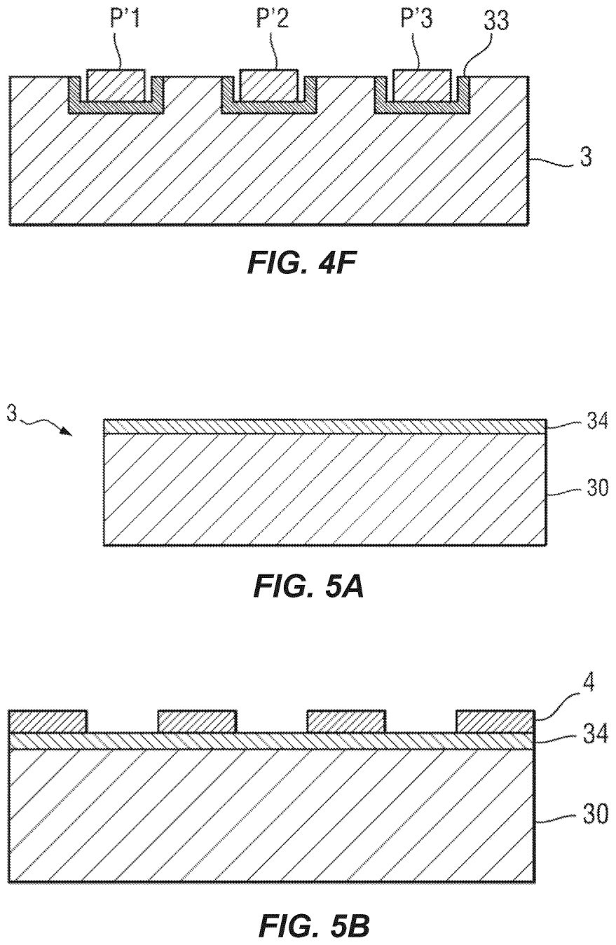

FIGS. 4A to 4F illustrate different steps of preparing the receiver substrate and transferring the tiles from the temporary substrate onto the receiver substrate, when the receiver substrate is a bulk substrate.

With reference to FIG. 4A, the receiver substrate 3 is a bulk substrate made from the second material.

With reference to FIG. 4B, a mask 4 is formed on the substrate 3, the mask having openings in the position of the cavities to be formed.

With reference to FIG. 4C, the second material exposed by the openings in the mask 4 is etched in order to form cavities C1, C2, C3. The etching time is adjusted as a function of the desired depth of the cavities.

The mask 4 is then removed so as to free the surface of the substrate 3. The substrate thus obtained can be used as a receiver substrate for receiving the tiles.

In one optional embodiment, illustrated in FIG. 4D, before the receiver substrate and the temporary substrate are assembled, an electrically insulating layer 33 can be formed on the surface of the substrate 3 so as to cover the walls and the bottom of the cavities. The insulating layer 33 makes it possible to electrically insulate the tiles that will be transferred into the cavities from the rest of the substrate 3.

With reference to FIG. 4E, the receiver substrate 3 and the temporary substrate 20 are assembled, placing the tiles P1, P2, P3 and the corresponding cavities C1, C2, C3 facing each other (in this figure, the substrate from FIG. 4D is shown, but the electrically insulating layer 33 could optionally be eliminated).

The adhesion of the substrates 3 and 20 takes place via the tiles and the bottom of the cavities.

With reference to FIG. 4F, the intermediate substrate is removed. In the embodiment illustrated, the tiles have a weakened zone 11. As a result, the intermediate substrate and the rest of the tiles are removed by detachment along the weakened zone 11. Only the tile portions P′1, P′2, P′3 are thus transferred onto the receiver substrate.

In other embodiments (not illustrated), the intermediate substrate can be removed by grinding the substrate from the face opposite the receiver substrate, until the main surface of the substrate 3 is reached.

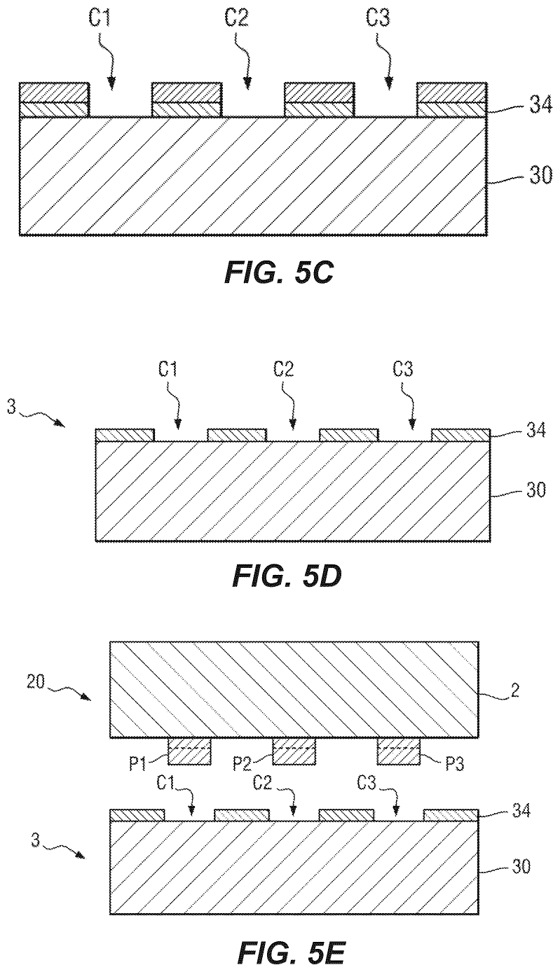

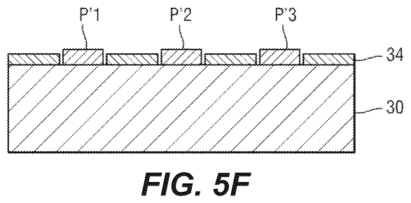

FIGS. 5A to 5F illustrate different steps of preparing the receiver substrate and transferring the tiles from the temporary substrate onto the receiver substrate, when the receiver substrate comprises a substrate made from the second material covered with an electrically insulating layer.

With reference to FIG. 5A, the receiver substrate 3 comprises a base substrate 30 made from the second material covered with an electrically insulating layer 34.

With reference to FIG. 5B, a mask 4 is formed on the electrically insulating layer 34, the mask having openings in the position of the cavities to be formed.

With reference to FIG. 5C, the electrically insulating material exposed by the openings in the mask 4 is etched, preferably over the entire thickness of the electrically insulating layer 34, in order to form cavities C1, C2, C3. The base substrate 30 effectively forms an etch-stop layer.

With reference to FIG. 5D, the mask 4 is removed so as to free the surface of the electrically insulating layer 34. The substrate thus obtained can be used as a receiver substrate for receiving the tiles.

With reference to FIG. 5E, the receiver substrate 3 and the temporary substrate 20 are assembled, placing the tiles P1, P2, P3 and the corresponding cavities C1, C2, C3 facing each other.

The adhesion of the substrates 3 and 20 takes place via the tiles and the bottom of the cavities.

With reference to FIG. 5F, the intermediate substrate is removed. In the embodiment illustrated, the tiles have a weakened zone 11. As a result, the intermediate substrate and the rest of the tiles are removed by detachment along the weakened zone 11. Only the tile portions P′1, P′2, P′3 are thus transferred onto the receiver substrate.

In other embodiments (not illustrated), the intermediate substrate can be removed by grinding the substrate from the face opposite the receiver substrate, until the main surface of the substrate 3 is reached.

1. A method of manufacturing a composite structure including at least two tiles on a substrate, the method comprising:
forming a temporary substrate comprising an intermediate substrate and a plurality of tiles of a first material placed on the intermediate substrate
assembling the temporary substrate with a receiver substrate of a second material different from the first material via the tiles; and
removing the intermediate substrate so as to transfer at least a portion of the tiles to the receiver substrate to form the composite structure;
wherein the receiver substrate comprises a main surface from which extend cavities extend, the receiver substrate being assembled on the temporary substrate on the side of the main surface so that each tile is received in a respective cavity, and wherein after the intermediate substrate has been removed, free surfaces of the portions of the tiles are substantially aligned with the main surface of the receiver substrate.

2. The method of claim 1, wherein the of forming the temporary substrate comprises forming a weakened zone of each tile defining a respective tile portion to be transferred, and the removing the intermediate substrate comprises detaching each tile portion along the weakened zone.

3. The method of claim 2, wherein the forming of the weakened zone comprises implanting atomic species in each tile.

4. The method of claim 1, wherein the forming of the temporary substrate comprises taking each tile from at least one donor substrate of the first material and placing each tile on the intermediate substrate, each donor substrate having a smaller diameter than the intermediate substrate.

5. The method of claim 1, wherein the second material is a semiconductor material, a piezoelectric material, or glass.

6. The method of claim 5, wherein the receiver substrate is a semiconductor-on-insulator substrate comprising in succession a base substrate, an electrically insulating layer and a layer of the second material defining the main surface of the receiver substrate, and wherein the cavities are formed in the layer of the second material as far as the electrically insulating layer.

7. The method of claim 5, wherein the cavities are formed in a surface region of the receiver substrate comprising the second material.

8. The method of claim 6, wherein at least part of walls within at least one of the cavities is covered with an electrically insulating film, so as to electrically insulate the respective portion from the receiver substrate.

9. The method of claim 5, wherein the receiver substrate comprises at least one surface layer of the second material covered with an electrically insulating layer and the cavities are formed in the electrically insulating layer.

10. The method of claim 1, wherein the temporary substrate is assembled on the receiver substrate by molecular adhesion.

11. The method of claim 1, wherein each tile has a thickness of between 20 μm and 1,000 μm, and the transferred portion of each tile has a thickness of between 30 nm and 1.5 μm.

12. The method of claim 11, wherein each cavity has a depth of between 30 nm and 1.5 μm.

13. The method of claim 1, wherein, following the removing the intermediate substrate the free surfaces of the tile portions are raised relative to the main surface of the receiver substrate and wherein the method further comprises polishing the free surfaces.

14. The method of claim 1, wherein the first material is selected from:
a semiconductor material;
a piezoelectric material; and/or
an electrically insulating material.

15. The method of claim 1, further comprising, before of assembling the temporary substrate and the receiver substrate, forming by epitaxy at least one additional layer of a third material on each tile.

16. The method of claim 1, wherein the cavities are formed by chemical etching through a mask having openings in the positions of the cavities.

17. The method of claim 1, wherein each cavity is sized to receive a single tile, each cavity being a same shape as the tile respectively received therein.

18. A composite structure, comprising:
at least two tiles of a first material; and
a receiver substrate of a second material different from the first material, the receiver substrate having a main surface;
wherein the tiles are arranged in respective cavities extending in the receiver substrate from the main surface, so that a free surface of each of the tiles is substantially aligned with the main surface of the receiver substrate.

19. The composite structure of claim 18, wherein the second material is a bulk semiconductor material, a piezoelectric material, glass, or a stack of a plurality of layers of different semiconductor materials.

20. The composite structure of claim 19, wherein the receiver substrate is a semiconductor-on-insulator substrate comprising in succession a base substrate, an electrically insulating layer and a layer of the second material defining the main surface of the receiver substrate, and wherein the cavities extend in the layer of the second material as far as the electrically insulating layer.

21. The composite structure of claim 19, wherein the cavities extend in a surface region of the receiver substrate comprising the second material.

22. The composite structure of claim 20, wherein the cavities extend in a surface region of the receiver substrate comprising the second material, and at least part of the walls of at least one of the cavities is covered with an electrically insulating film.

23. The composite structure of claim 19, wherein the receiver substrate comprises at least one surface layer of the second material covered with an electrically insulating layer and the cavities are formed in the electrically insulating layer.

24. The composite structure of claim 18, wherein the first material is selected from:
a semiconductor material;
piezoelectric material; and/or
an electrically insulating material.
